(19) United States
(12) Patent Application Publication
(10) Pub. No.: US 2023/0021587 A1
(43) Pub. Date: Jan. 26, 2023

(54) CONNECTOR-MOUNTED BOARD MANUFACTURING METHOD AND ELECTRONIC UNIT

(71) Applicant: Yazaki Corporation, Tokyo (JP)

(72) Inventor: Ryo HIRAMATSU, Makinohara-shi (JP)

(73) Assignee: Yazaki Corporation, Tokyo (JP)

(21) Appl. No.: 17/836,234

(22) Filed: Jun. 9, 2022

(30) Foreign Application Priority Data
Jul. 14, 2021 (JP) 2021-116575

(51) Int. Cl. H01R 43/20; H01R 12/58; H01R 13/506; H01R 13/04; H05K 3/34

(52) U.S. Cl. CPC H01R 43/205; H01R 12/58; H01R 13/506; H01R 13/04; H05K 3/3447; H05K 1/18

(57) ABSTRACT

Provided is a connector-mounted board manufacturing method for manufacturing a connector-mounted board, the connector-mounted board including a circuit board, on which a terminal and an electronic component are mounted, and a connector housing attached to the terminal. The connector-mounted board manufacturing method includes: executing a mounting process of mounting the terminal and the electronic component on the circuit board; and executing an attaching process of attaching the connector housing to the terminal after the mounting process has been executed.

### CROSS-REFERENCE TO RELATED APPLICATIONS

This application is based on and claims priority under 35 USC 119 from Japanese Patent Application No. 2021-116575 filed on Jul. 14, 2021, the contents of which are incorporated herein by reference.

### TECHNICAL FIELD

The present disclosure relates to a connector-mounted board manufacturing method for manufacturing a connector-mounted board including a circuit board on which a terminal and an electronic component are mounted and a connector housing, and also relates to an electronic unit in which a casing for covering a circuit board is attached to a connector- mounted board.

### BACKGROUND ART

In the related art, there has been proposed a connector-mounted board manufacturing method for manufacturing a connector-mounted board by preparing a connector in advance, in which a terminal is press-fitted and held in a connector housing, and then mounting the connector on a circuit hoard (for example, performing soldering by a reflow treatment) (see, for example, JP-A-2021-005634, JP-A-2021-005635 and JP-A-2021-040436).

SUMMARY OF INVENTION

In the connector-mounted board manufacturing method of the type described above, typically, the connector housing is disposed in a manner of being placed on a mounting surface of the circuit board, positioning is implemented by inserting a leg portion of the terminal into a through hole of the circuit board, and then the leg portion of the terminal is soldered to the through hole (that is, a circuit pattern). The connector-mounted board in the related art that is manufactured using such a manufacturing method has a dimension that is a sum of a height of the connector housing and a thickness of the circuit board in a thickness direction of the circuit board. From the viewpoint of reducing the thickness and height of the connector- mounted board, it may be required to reduce this dimension as much as possible. However, if a wall thickness of the connector housing or the thickness of the circuit board is carelessly reduced, there is a concern that structural strength and durability originally required for the connector-mounted board may be impaired. Therefore, it is generally difficult to reduce the thickness and height of the connector-mounted board while maintaining an original function of the connector-mounted board.

An object of the present disclosure is to provide a connector-mounted board manufacturing method capable of manufacturing a connector-mounted board having a reduced height without impairing an original function of the connector-mounted board, and to provide an electronic unit using the connector-mounted board manufactured using this method.

The present disclosure provides a connector-mounted board manufacturing method for manufacturing a connector-mounted board, the connector-mounted board including a circuit board, on which a terminal and an electronic component are mounted, and a connector housing attached to the terminal, the connector-mounted board manufacturing method including: executing a mounting process of mounting the terminal and the electronic component on the circuit board; and executing, after execution of the mounting process, an attaching process of attaching the connector housing to the terminal.

The present disclosure provides an electronic unit including: a circuit board on which a terminal and an electronic component are mounted, a connector housing attached to the terminal, and a casing disposed so as to cover the circuit board, in which the terminal includes: an engaging portion configured to position the terminal with respect to the circuit board; and a board connecting portion provided at a position different from that of the engaging portion, the board connecting portion being configured to be electrically connected to a circuit pattern of the circuit board, and in which the terminal is mounted on the circuit board by soldering the board connecting portion to the circuit pattern in a state where the engaging portion is engaged with the circuit board,

The present disclosure has been briefly described above. Further, details of the present disclosure will be clarified by reading a mode (hereinafter, referred to as an “embodiment”) for carrying out the invention to be described below with reference to the accompanying drawings.

### BRIEF DESCRIPTION OF DRAWINGS

FIG. 1 is a perspective view of an electronic unit using a connector-mounted board according to an embodiment of the present disclosure.

FIG. 2 is a cross-sectional view taken along a line A-A in FIG. 1.

FIG. 3 is a perspective view of a terminal used in the connector-mounted board.

FIG. 4 is a diagram for illustrating a mounting process of mounting a terminal and an electronic component on a circuit board.

FIG. 5 is a diagram for illustrating an attaching process of attaching a connector housing to a terminal.

FIG. 6 is a diagram for illustrating a process of manufacturing an electronic unit by attaching a casing to a connector housing of a connector-mounted hoard.

### DESCRIPTION OF EMBODIMENTS

### Embodiment

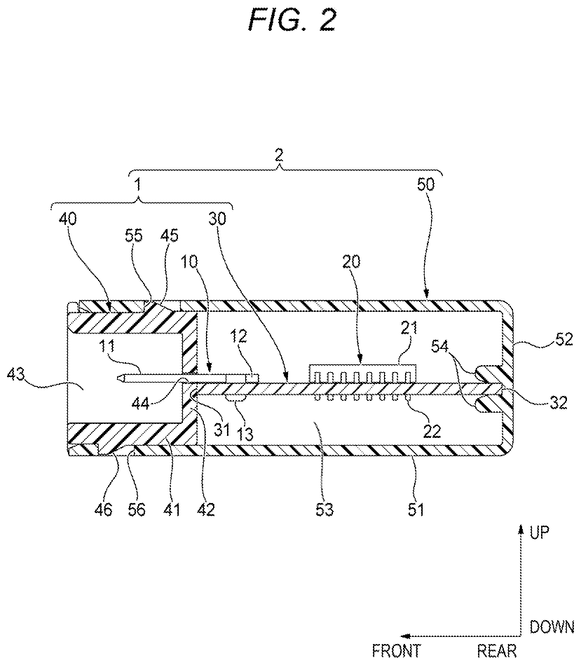

Hereinafter, a connector-mounted board 1 and an electronic unit 2 using the connector-mourned board 1 according to an embodiment of the present disclosure will be described with reference to the drawings. As illustrated in FIG. 2, the connector-mounted board 1 includes a circuit board 30 on which a plurality of terminals 10 and a plurality of electronic components 20 are mounted, and a connector housing 40 to which the terminals 10 are attached. The electronic unit 2 is manufactured by attaching a casing 50 to the connector housing 40 of the connector-mounted board 1.

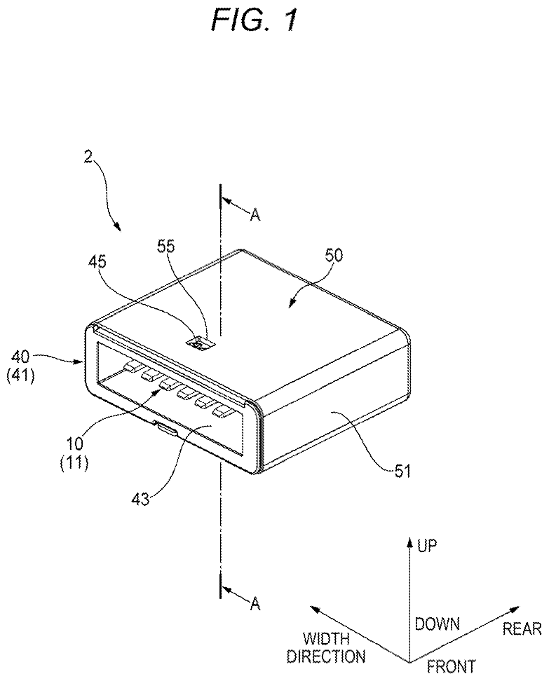

Hereinafter, for convenience of description, as illustrated in FIGS. 1 to 6, a “front-rear direction”, a “width direction”, and an “up-down direction” are defined. The “front-rear direction”, the “width direction”, and the “up-down direction” are orthogonal to one another. The front-rear direction coincides with a fitting direction of the connector housing 40 and a mating connector (not shown), a side of advancing to fit with the mating connector is set as a front side, and a side of retreating from the fitting is set as a rear side. Hereinafter, the respective members constituting the connector-mounted board 1 and the casing 50 will be described in order.

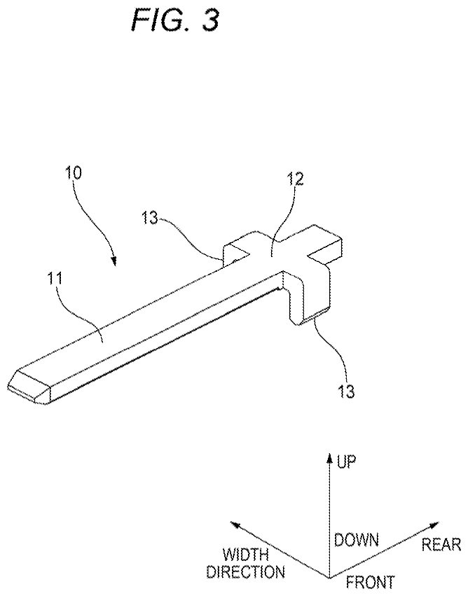

First, the terminal 10 will be described. Each of the plurality of terminals 10 to be mounted on the circuit board 30 is manufactured by performing a punching process, a bending process, and the like on one metal plate. In this example, the plurality of terminals 10 have the same shape. As illustrated in FIG. 3, the terminal 10 has a rod-like shape extending in the front-rear direction as a whole. The terminal 10 integrally includes a contact portion 11 located in the vicinity of a front end portion, a board connecting portion 12 located in the vicinity of a rear end portion, and a pair of engaging portions 13 protruding outward in the width direction from both side surfaces of the board connecting portion 12 in the width direction, curved downward, and extending toward the circuit board 30. The contact portion 11 and the board connecting portion 12 of the terminal 10 are arranged in a manner of extending along an upper surface (mounting, surface) of the circuit board 30.

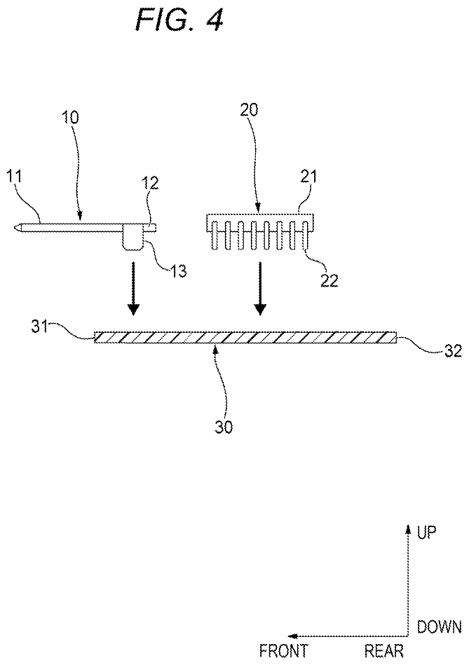

When mounting the terminal 10 on the circuit hoard 30, the pair of engaging portions 13 are inserted into a pair of positioning holes (not shown) formed in the vicinity of a front end edge 31 (see FIG. 4 and the like) of the circuit hoard 30, and a lower surface of the board connecting portion 12 is directly soldered to a circuit pattern (not shown) positioned between the pair of positioning holes in the vicinity of the front end edge 31 of the circuit board 30 (see FIGS. 2, 4, and 5). The lower surface of the board connecting portion 12 may be flush with a lower surface of the contact portion 11, or may be positioned on an upper side or a lower side of the lower surface of the contact portion 11. In this way, the terminal 10 does not have a foot portion that is electrically connected to the circuit pattern of the circuit board 30 by being inserted into and soldered to the circuit board 30, and that is used in the above-described connector-mounted board in the related art.

Next, the electronic component 20 will be described. Each of the plurality of electronic components 20 to be mounted on the circuit board 30 is typically a large-scale integrated circuit (LSI), and in this example, includes a main body portion 21 extending in the front-rear direction, and a plurality of lead portions (toot portions) 22 that extend downward from a plurality of positions on both side edges of the main body portion 21 in the width direction and that are arranged side by side in the front-rear direction. The plurality of electronic components 20 may have the same shape or different shapes. When mounting the electronic component 20 on the circuit board 30, the plurality of lead portions 22 of the electronic component 20 are inserted into and soldered to a plurality of through holes (not shown) formed in a central portion of the circuit board 30 in the front-rear direction (see FIGS. 2, 4, and 5).

Next, the circuit board 30 will be described, In this example, the circuit board 30 includes a rectangular flat plate-shaped resin board extending in the front-rear direction and the width direction, and a metal circuit pattern having a predetermined pattern formed on an upper surface of the board. In the vicinity of the front end edge 31 of the circuit board 30, a plurality of pairs of positioning holes (not shown), each pair being for inserting one pair of engaging portions 13 of the terminal 10, are respectively formed at a plurality of positions in the width direction (a direction along the front end edge 31) corresponding to the plurality of terminals 10. A plurality of through holes (not shown) for inserting the lead portions 22 of the plurality of electronic components 20 are formed in the central portion of the circuit board 30 in the front-rear direction.

Next, the connector housing 40 will be described. The connector housing 40 is a resin molded product, and as illustrated in FIGS. 2, 5, and 6, includes a rectangular tubular main body portion 41 that extends in the front-rear direction and that is long in the width direction. A rear end of the main body portion 41 is closed by a rectangular flat plate-shaped rear end wall 42, while a front end of the main body portion 41 is open. When fitting the connector housing 40 with a mating connector, the mating connector is inserted and fitted into an internal space 43 of the main body portion 41 through the front end opening of the main body portion 41.

As illustrated in FIGS. 2, 5, and 6, a plurality of insertion holes (through holes) 44 extending in the front-rear direction are provided side by side in the width direction in the rear end wall 42 correspondingly to the plurality of terminals 10. The contact portion 11 of the terminal 10 is inserted into a corresponding insertion hole 44 from a rear side.

An upper locking projection 45 is formed on an upper surface (an outer peripheral surface) of a central portion of an upper wall of the main body portion 41 in the width direction, and a lower locking projection 46 is formed on a lower surface (an outer peripheral surface) of a central portion of a lower wall of the main body portion 41 in the width direction. When the casing 50 is attached to the connector housing 40 of the connector-mounted board 1, the upper locking projection 45 and the lower locking projection 46 engage with an upper locking hole 55 and a lower locking hole 56 of the casing 50, respectively, and thus a function of preventing the casing 50 from being separated from the connector housing 40 (coming off from the rear side) is achieved.

The connector housing 40 is made of a non-heat-resistant resin having a lower heat-resistant temperature than a treatment temperature at the time of reflow treatment performed in a heating oven when mounting (soldering) the terminals 10 and the electronic components 20 on the circuit board 30. Advantages obtained thereby will be described later.

Next, the casing 50 will be described. The casing 50 is a resin molded product, and as illustrated in FIGS. 2, 5, and 6, includes a rectangular tubular main body portion 51 extending in the front-rear direction and the width direction. A rear end of the main body portion 51 is closed by a rectangular flat plate-shaped rear end wall 52, while a front end of the main body portion 51 is open. When attaching the casing 50 to the connector housing 40 of the connector-mounted board 1, the connector housing 40 is inserted into an internal space 53 of the main body portion 51 through the front end opening of the main body portion 51,

A pair of upper and lower holding pieces 54 for holding a rear end edge 32 (see FIG. 2 and the like) extending in the width direction of the circuit board 30 are formed on a front surface (an inner surface facing the internal space 53) of the rear end wall 52. When the casing 50 is attached to the connector housing 40 of the connector-mounted board 1, the rear end edge 32 of the circuit board 30 is inserted between the pair of upper and lower holding pieces 54, and is held in a manner of being sandwiched in the up-down direction by the pair of upper and lower holding pieces 54.

An upper locking hole (through hole) 55 is formed in a central portion of an upper wall of the main body portion 51 in the width direction correspondingly to the upper locking projection 45 of the connector housing 40, and a lower locking hole (through hole) 56 is formed in a central portion of a lower wall of the main body portion 51 correspondingly to the lower locking projection 46 of the connector housing 40. The members, which constitute the connector-mounted board 1, and the casing. 50 have been described above.

Next, a connector-mounted board manufacturing method for manufacturing the connector-mounted board 1 will be described. In order to manufacture the connector-mounted board 1, first, the plurality of terminals 10 and the plurality of electronic components 20 are mounted on the circuit board 30 (a mounting process). Therefore, first, a solder paste is applied to the upper surface of the circuit board 30 so as to cover a plurality of circuit patterns at a plurality of positions corresponding to arrangement positions of the plurality of terminals 10 (board connecting portions 12) and cover the plurality of through holes for inserting the plurality of lead portions 22 of the plurality of electronic components 20.

Next, as illustrated in FIG. 4, the plurality of terminals 10 and the plurality of electronic components 20 are disposed above the circuit board 30. Next, the plurality of terminals 10 and the plurality of electronic components 20 are brought closer to the circuit board 30 in the up-down direction until the plurality of terminals 10 and the plurality of electronic components 20 are placed on the upper surface of the circuit board 30 so that the pair of engaging portions 13 of each terminal 10 are inserted into the corresponding pair of positioning holes of the circuit board 30 and the plurality of lead portions 22 of each electronic component 20 are inserted into the corresponding plurality of through holes of the circuit board 30.

In this way, the pair of engaging portions 13 of each terminal 10 are inserted into the corresponding pair of positioning holes of the circuit board 30, so that each terminal 10 is appropriately positioned on the circuit board 30. As a result, a tip portion of the contact portion 11 of each terminal 10 is disposed protruding forward from the front end edge 31 of the circuit board 30, and the lower surface of the board connecting portion 12 of each terminal 10 is disposed facing the circuit pattern of the circuit board 30 via the solder paste.

Next, the reflow treatment is performed on the solder. Specifically, the circuit board 30 on which the plurality of terminals 10 and the plurality of electronic components 20 are placed is disposed in a heating oven set to a high treatment temperature, so that the solder paste on the circuit board 30 is heated and melted. After the reflow treatment, the melted solder is solidified, whereby the board connecting portion 12 of each terminal 10 and the circuit pattern of the circuit board 30 are directly soldered (fixed and electrically connected via the solder), and the plurality of lead portions 22 of each electronic component 20 are soldered to the plurality of through holes (fixed and electrically connected via the solder) respectively. The treatment temperature of the reflow treatment is determined according to a melting point of the solder to be used, and is generally about 180° C. to 230° C.

Accordingly, the mounting of the plurality of terminals 10 and the plurality of electronic components 20 on the circuit board 30 is completed (the mounting process is completed). In this way, the board connecting portion 12 of the terminal 10 extending along the upper surface of the circuit board 30 is directly soldered to the circuit pattern of the circuit board 30. Therefore, since the foot portion of the terminal to be inserted into the circuit board 30 as in the connector-mounted board in the related art is unnecessary, a height of the terminal 10 itself can be reduced.

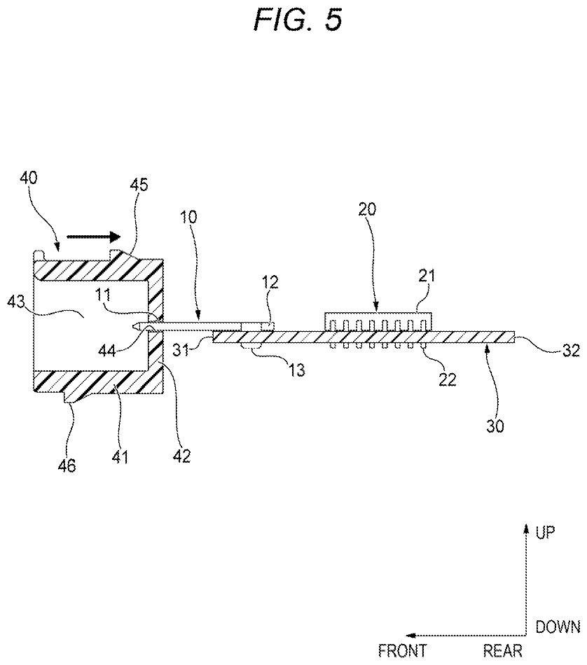

When the mounting of the plurality of terminals 10 and the plurality of electronic components 20 on the circuit board 30 is completed, the connector housing 40 is then attached to the plurality of terminals 10 (an attaching process). Therefore, first, the connector housing 40 is disposed in front of the circuit hoard 30. Next, as illustrated in FIG. 5, the circuit board 30 and the connector housing 40 are brought closer to each other in the front-rear direction until the front end edge 31 of the circuit board 30 comes into contact with the ear end surface of the connector housing 40 (the rear end wall 42) so that the contact portions 11 of the plurality of terminals 10 are respectively inserted into the plurality of insertion holes 44 of the connector housing 40.

When the front end edge 31 of the circuit board 30 comes into contact with the rear end surface of the connector housing 40 (the rear end wall 42), the attachment of the connector housing 40 to the plurality of terminals 10 is completed (the attaching process is completed). As a result, the connector-mounted board 1 illustrated in FIG. 2 is manufactured (completed). In the completed state of the connector-mounted board 1, the tip portions of the contact portions 11 of the plurality of terminals 10 are arranged side by side in the width direction in the internal space 43 of the connector housing 40.

In the connector-mounted board 1, the circuit board 30 and the connector housing 40 are arranged so as not to overlap each other in the up-down direction (a thickness direction of the circuit board 30) (see FIG. 2). Therefore, it is possible to manufacture the connector-mounted board 1 having a reduced height than the connector-mounted board in the related art.

Further, in the connector-mounted board 1, after the plurality of terminals 10 and the plurality of electronic components 20 are mounted on the circuit board 30 through the ram treatment, the connector housing 40 is attached to the plurality of terminals 10. Accordingly, since the connector housing 40 is not exposed to a high temperature in the reflow treatment, the connector housing 40 is made of a non-heat-resistant resin having a low heat-resistant temperature, as described above. Therefore, the manufacturing cost of the connector housing 40 (and thus the manufacturing cost of the connector-mounted board 1) can be reduced.

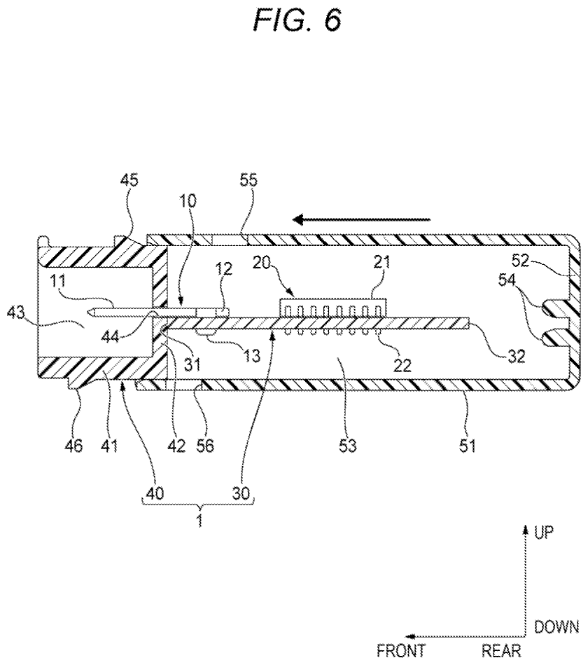

The casing 50 is attached to the connector housing 40 of the manufactured (completed) connector-mounted board 1 in order to attach the casing 50 to the connector housing 40, first, the casing 50 is disposed behind the circuit board 30 of the connector-mounted board 1. Next, as illustrated in FIG. 6, the casing 50 and the connector-mounted board 1 are brought closer to each other in the front-rear direction until the upper locking hole 55 and the lower locking hole 56 of the casing 50 are locked with the upper locking projection 45 and the lower locking projection 46 of the connector housing 40, respectively, so that the circuit board 30 and the connector housing 40 are inserted into the internal space 53 of the casing 50 in this order through the front end opening of the casing 50.

When the upper locking hole 55 and the lower locking hole 56 are locked with the upper locking projection 45 and the lower locking projection 46, respectively, the attachment of the casing 50 to the connector housing 40 is completed. As a result, the electronic unit 2 illustrated in FIGS. 1 and 2 is manufactured (completed).

In the completed state of the electronic unit 2, as illustrated in FIG. 2, the casing 50 accommodates the circuit board 30 in the internal space 53 so that the circuit board 30 is covered. The rear end edge 32 of the circuit board 30 is positioned between the pair of upper and lower holding pieces 54 of the casing 50 and is sandwiched in the up-down direction by the pair of upper and lower holding pieces 54. The front end opening of the connector housing 40 (main body portion 41) is disposed at the same position in the front-rear direction as the front end opening of the casing 50 (main body portion 51).

A mating connector is to be fitted to the connector housing 40 of the electronic unit 2. At the time of fitting, the mating connector is inserted into the internal space 43 of the main body portion 41 through the front end opening of the connector housing 40 (main body portion 41). Accordingly, the plurality of terminals 10 (male terminals) located in the internal space 43 of the connector housing 40 are electrically connected to a plurality of female terminals (not shown) accommodated in the mating connector

As described above, the electronic unit 2 is implemented by attaching the casing 50 to the connector-mounted board 1 having a reduced height as compared with the connector-mounted board in the related art. Therefore, it is possible to obtain the electronic unit 2 that can be reduced in height as compared with the case of using the connector-mounted board in the related art. Therefore, the electronic unit 2 can be disposed in a relatively narrow part (a part where the electronic unit is required to have a reduced height) such as the inside of a roof or the inside of a door of a vehicle, for example.

As described above, according to the connector-mounted board manufacturing method for manufacturing the connector-mounted board 1 according to the present embodiment, after the terminals 10 and the electronic components 20 are mounted on the circuit board 30, the connector housing 40 is attached to the terminals 10. Therefore, an occurrence that the shape and arrangement of the connector housing are limited for positioning the terminals as in the above-described connector-mounted board in the related art is avoided. Therefore, according to the connector-mounted board manufacturing method for manufacturing the connector-mounted board 1 of the present embodiment, the connector-mounted board 1 having a reduced height than the connector-mounted board in the related art can be manufactured.

Further, the pair of engaging portions 13 of the terminal 10 are engaged with the pair of positioning holes of the circuit board 30, so that the terminal 10 is positioned with respect to the circuit board 30. Therefore, without an occurrence that a connector housing is used as in the connector-mounted board in the related art, it is possible to appropriately position the terminal 10 on the circuit board 30.

Further, the board connecting portion 12 extending along the mounting surface (upper surface) of the circuit board 30 is directly soldered to the circuit pattern of the circuit board 30, Accordingly, a foot portion to be inserted into the circuit board as in the connector-mounted board in the related art is unnecessary, and thus the height of the terminal 10 itself can be reduced.

Further, since a foot portion to be inserted into the circuit board 30 as in the connector-mounted board in the related art is unnecessary, the height of the terminal 10 itself can be reduced.

Further, the terminals 10 and the electronic components 20 are mounted on the circuit board 30 through the reflow treatment, and thereafter the connector housing 40 is attached to the terminals 10. Accordingly, since the connector housing 40 is not exposed to a high temperature in the reflow treatment, the connector housing 40 is made of a non-heat-resistant resin having a low heat-resistant temperature. In general, a non-heat-resistant resin is less expensive than a heat-resistant resin that can withstand a high temperature, Therefore, the manufacturing cost of the connector housing 40 (and thus the manufacturing cost of the connector-mounted board 1) can be reduced,

Further, the circuit board 30 and the connector housing 40 are arranged so as not to overlap with each other in the thickness direction of the circuit board 30. Therefore, it is possible to manufacture the connector-mounted board 1 having a reduced height than the connector-mounted board in the related art.

Further, according to the electronic unit 2, as described above, the casing 50 covering the circuit board 30 is attached to the connector-mounted board 1 haying a reduced height as compared with the connector-mounted board in the related art. Accordingly, it is possible to obtain the electronic unit 2 that can be reduced in height as compared with the case of using the connector-mounted board in the related art.

### Other Embodiments

The present disclosure is not limited to the above-described embodiment, and various modifications can be used within the scope of the present invention. For example, the present disclosure is not limited to the above-described embodiment, and may be appropriately modified, improved or the like. In addition, the material, shape, size, number, arrangement position, and the like of each component in the above-described embodiment are optional and are not limited as long as the present invention can be achieved.

Here, characteristics of the embodiment of the connector-mourned board manufacturing method for manufacturing the connector-mourned board 1 and the embodiment of the electronic unit 2 according to the present disclosure described above will be briefly summarized and listed in [1] to [11] below.

[1] A connector-mounted board manufacturing method for manufacturing a connector-mounted board (1), the connector-mounted board (1) including a circuit board. (30), on which a terminal (10) and an electronic component (20) are mounted, and a connector housing (40) attached to the terminal (10), the connector-mounted board manufacturing method including:

executing a mounting process of mounting the terminal (10) and the electronic. component (20) on the circuit board (30); and

executing, after execution of the mounting process, an attaching process of attaching the connector housing (40) to the terminal (10).

According to the connector-mounted board manufacturing method having the above configuration of [1], after the terminal and the electronic component are mounted on the circuit board, the connector housing is attached to the terminal. Therefore, a limitation on the manufacturing method, such as placing a connector on a mounting surface of the circuit board in order to insert a leg portion of the terminal into a through hole of the circuit board, or a limitation on the shape, such as providing a positioning structure in the connector housing so as to be suitable for such a limited manufacturing method, as in the above-described connector-mounted board manufacturing method in the related art, is avoided. In other words, the manufacturing method for the present disclosure has a higher degree of freedom in designing the manufacturing method and the structure of the connector housing as compared with the manufacturing method in the related art. Therefore, for example, by disposing the connector housing at an outer side of a peripheral edge of the circuit board instead of placing the connector housing on the mounting surface, it is possible to avoid overlapping between a height of the connector housing and a thickness of the circuit board, and it is possible to favorably reduce the thickness and a height of the connector-mounted board. Therefore, it is possible to manufacture a connector-mounted board having a reduced height without impairing an original function of the connector-mounted board, as compared with a connector-mounted board in the related art.

[2] The connector-mounted board manufacturing method according to [1],

in which the terminal (10) includes an engaging portion (13) configured to position the terminal with respect to the circuit board (30), and

in which in the mounting process, the terminal is mounted on the circuit board (30) in a state where the engaging portion (13) is engaged with the circuit board (30) in the mounting process.

According to the connector-mounted board manufacturing method having the above configuration of [2], the terminal is positioned with respect to the circuit board by engaging the engaging portion of the terminal with the circuit board. Therefore, it is possible to appropriately position the terminal on the circuit board by the terminal alone without an occurrence that the connector housing is used for positioning the terminal as in the connector-mounted board in the related art.

[3] The connector-mounted board manufacturing method according to [1] or [2].
in which the terminal (10) includes:
   a board connecting portion (12) extending along a mounting surface of the circuit board (30); and
   a contact portion (11) extending outward from a peripheral edge of the circuit board (30), and
in which in the mounting process, the terminal (10) is mounted on the circuit board (30) by soldering a surface of the board connecting portion (12) and a circuit pattern of the circuit board (30), the surface of the board connecting portion (12) facing the mounting surface.

According to the connector-mounted board manufacturing method having the above configuration of [3], the board connecting portion extending along the mounting surface of the circuit board is directly soldered to the circuit pattern of the circuit board. Therefore, since a foot portion to be inserted into the through hole of the circuit board as in the connector- mounted board in the related art is unnecessary, a height of the terminal itself can be reduced The terminal and the electronic component may be collectively mounted on the circuit board, or the terminal and the electronic component may be individually mounted on the circuit board.

[4] The connector-mounted board manufacturing method according to any one of [1]to [3],

in which the terminal (10) does not have a foot portion for board connection to be inserted and soldered to the circuit board (30).

According to the connector-mounted board manufacturing method having the above configuration of [4], since the leg portion to be inserted into the through hole of the circuit board as in the connector-mounted board in the related art is unnecessary, it is possible to reduce the height of the terminal itself

[5] The connector-mounted board manufacturing method according to any one of [1] to [4],

in which the mounting process includes a reflow treatment of collectively soldering and mounting the terminal (10) and the electronic component (20) on the circuit board (30) in a heating oven, and

in which the connector housing (40) is made of a non-heat-resistant resin having a heat-resistant temperature lower than a treatment temperature in the reflow treatment.

According to the connector-mounted board manufacturing method having the above configuration of [5], the terminal and the electronic component are mounted on the circuit board through the reflow treatment, and thereafter the connector housing is attached to the terminal. Accordingly, since the connector housing is not exposed to a high temperature in the reflow treatment, the connector housing is made of a non-heat-resistant resin having a low heat-resistant temperature. In general, a non-heat-resistant resin is less expensive than a heat- resistant resin that can withstand a high temperature, Therefore, the manufacturing cost of the connector housing (and thus the manufacturing cost of the connector-mounted board) can be reduced.

[6] The connector-mounted board manufacturing method according to any one of [1] to [5],

in which in the attaching process, the connector housing (40) is attached to the terminal (10) in a positional relationship in which the circuit board (30) and the connector housing (40) do not overlap each other in a thickness direction of the circuit board (30),

According to the connector-mounted board manufacturing method having the above configuration of [6], the circuit hoard and the connector housing are arranged so as not to overlap each other in the thickness direction of the circuit board. With this arrangement, it is possible to avoid overlapping between the height of the connector housing and the thickness of the circuit board, and it is possible to favorably reduce the thickness and the height of the connector-mounted board.

[7] An electronic unit (2) including:
a circuit board (30) on which a terminal (10) and an electronic component (20) are mounted;
a connector housing (40) attached to the terminal (20); and
a casing (50) disposed so as to cover the circuit board (30),
in which the terminal (10) includes:
   an engaging portion (13) configured to position the terminal with respect to the circuit hoard (30); and
   a board connecting portion (12) provided at a position different from that of the engaging portion (13), the board connection portion (12) being configured to be electrically connected to a circuit pattern of the circuit board (30), and
in which the terminal (10) is mounted on the circuit board (30) by soldering, the board connecting portion (12) to the circuit pattern in a state where the engaging portion (13) is engaged with the circuit board (30).

According to the electronic unit having the above configuration of [7], as described above, the casing for covering the circuit board is attached to the connector-mounted board that is reduced in height as compared with a connector-mounted board in the related art. Since the connector-mounted board is reduced in thickness and height, it is possible to use a casing similarly reduced in thickness and height. Therefore, it is possible to reduce a thickness and a height of the electronic unit as compared with the case of using a connector-mounted board manufactured by using a manufacturing method in the related art

Further, similarly, the electronic unit having the following configurations [8] to [11] can also be reduced in thickness and height as compared with the case of using a connector- mounted board manufactured by using a manufacturing method in the related art.

[8] The electronic unit (2) according to [7],

in which the terminal (10) includes the board connecting portion (12) extending along a mounting surface of the circuit board (30) and a contact portion (11) extending outward from a peripheral edge of the circuit board (30), and the terminal (10) is mounted on the circuit hoard (30) by soldering a surface of the board connecting portion (12) and the circuit pattern of the circuit board (30), the surface of the board connecting portion (12) facing the mounting surface.

[9] The electronic unit (2) according to [7] or [8],

in which the terminal (10) does not have a foot portion for board connection to be inserted and soldered to the circuit hoard (30).

[10] The electronic unit (2) according, to any one of [7] to [9],

in which the connector housing is made of a non-heat-resistant resin having a heat-resistant temperature lower than a treatment temperature in a reflow treatment of soldering the terminal (10) to the circuit board (30) in a heating oven.

[11] The electronic unit (2) according to any one of [7] to [10]

in which the connector housing is attached to the terminal (10) in a positional relationship in which the circuit board (30) and the connector housing do not overlap in a thickness direction of the circuit board (30).

According to the present disclosure it is possible to provide a connector-mounted board manufacturing method capable of manufacturing a connector-mounted board having a reduced height without impairing an original function of the connector-mounted board, and to provide an electronic unit using the connector-mounted board manufactured in this method.

What is claimed is:

1. A connector-mounted board manufacturing method for manufacturing a connector-mounted board, the connector-mounted board comprising a circuit board, on which a terminal and an electronic component are mounted, and a connector housing attached to the terminal, the connector-mounted board manufacturing method comprising;
executing a mounting process of mounting the terminal and the electronic component on the circuit board; and
executing, after execution of the mounting process, an attaching process of attaching the connector housing to the terminal.

2. The connector-mounted board manufacturing method according to claim 1,
wherein the terminal comprises an engaging portion configured to position the terminal with respect to the circuit board, and
wherein in the mounting process, the terminal is mounted on the circuit board in a state where the engaging portion is engaged with the circuit board.

3. The connector-mounted board manufacturing method according to claim 1,
wherein the terminal comprises:
a board connecting portion extending along a mounting surface of the circuit board; and
a contact portion extending outward from a peripheral edge of the circuit board, and
wherein in the mounting process, the terminal is mounted on the circuit board by soldering a surface of the board connecting portion and a circuit pattern of the circuit board, the surface of the board connecting portion facing the mounting surface.

4. The connector-mounted board manufacturing method according to claim 1,
wherein the terminal does not have a foot portion for board connection to be inserted and soldered to the circuit board.

5. The connector-mounted board manufacturing method according to claim 1, wherein the mounting process comprises a reflow treatment of collectively soldering and mounting the terminal and the electronic component on the circuit board in a heating oven. and
wherein the connector housing is made of a non-heat-resistant resin having a heat-resistant temperature lower than a treatment temperature in the reflow treatment.

6. The connector-mounted board manufacturing method according to claim 1,
wherein in the attaching process, the connector housing is attached to the terminal in a positional relationship in which the circuit board and the connector housing do not overlap each other in a thickness direction of the circuit board,

7. An electronic unit comprising:
a circuit board on which a terminal and an electronic component are mounted;
a connector housing attached to the terminal; and
a casing disposed so as to cover the circuit board,
wherein the terminal comprises:
an engaging portion configured to position the terminal with respect to the circuit board: and
a board connecting portion provided at a position different from that of the engaging portion, the board connecting portion being configured to be electrically connected to a circuit pattern of the circuit board, and
wherein the terminal is mounted on the circuit board by soldering the board connecting portion to the circuit pattern in a state where the engaging portion is engaged with the circuit board.
